(19) United States
(12) Patent Application Publication
(10) Pub. No.: US 2020/0105750 A1
(43) Pub. Date: Apr. 2, 2020

(54) GATE-ALL-AROUND QUANTUM WELL COMPLEMENTARY INVERTER AND METHOD OF MAKING THE SAME

(71) Applicant: SiEn (QingDao) Integrated Circuits Co., Ltd, Qingdao (CN)

(72) Inventor: Deyuan Xiao, Shanghai (CN)

(21) Appl. No.: 16/556,134

(22) Filed: Aug. 29, 2019

(30) Foreign Application Priority Data
Sep. 28, 2018 (CN) 201811134891.4

(51) Int. Cl. H01L 27/092; H01L 29/06; H01L 29/423; H01L 29/778; H01L 29/786; H01L 29/66; H01L 21/02; H01L 21/311; H01L 21/8238

(52) U.S. Cl. CPC H01L 27/092; H01L 29/0673; H01L 29/42392; H01L 29/778; H01L 29/78651; H01L 29/78684; H01L 21/823807; H01L 29/66431; H01L 21/02603; H01L 21/02532; H01L 21/02236; H01L 21/31111; H01L 29/78696

(57) ABSTRACT

The present invention provides a gate-all-around quantum well complementary inverter comprises a first and a second field effect transistor (FET). Channels of the first and second FETs, each of which is surrounded by a gap area, are juxtaposed transversely. A source area and a drain area are positioned at a side of the channel. The channel comprises a semiconductor nano-sheet, a first semiconductor layer fully surrounding semiconductor nano-sheet and a second semiconductor layer fully surrounding the first semiconductor layer. The first semiconductor layer provides a quantum well for holes, and the second semiconductor layer provides a quantum well for electrons. A common gate electrode fully surrounds the gate layer of the first FET and the gate layer of the second FET. The structure of the disclosed device is compact enough to increase the density and improve the performance and simple enough to produce.

### FIELD OF THE INVENTION

The present invention generally relates to a semiconductor device. Specifically, the device of gate-all-around (GAA) quantum well complementary inverter and method of making the same are disclosed.

### BACKGROUND OF THE INVENTION

FinFET is a kind of field effect transistor (FET) with vertical fin-like structure. The 3D fin-like structure may form three gates to promote the power and efficiency. Current 14 nm and 10 nm chips and even the developing 7 nm chips which are just in test run phase are applied such FinFET chips for power supply. Recently, the FinFET chips are applied in servers, computers and systems, and they will be dominant in the future couple years.

The US Patent Publication No. US08350298B2, entitled “HYBRID MATERIAL INVERSION MODE GAA CMOSFET,” disclosed a GAA CMOS FET with mixed material. The cross section shape of the PMOS and NMOS channels in such transistor is like a track of a stadium, and the gate fully surrounds the surface of the PMOS or NMOS channels. Such GAA transistors show higher carrier mobility and prevent from poly depletion effect and short channel effect.

The GAA transistor of 5 nm node may be formed by horizontally stacking silicon nano-sheets to promote required power and performance for future application. The forth “gate” is opened by the vertical structure changed to the horizontal silicon layers. Then, electrical signals may be transmitted between transistors by passing across other transistors on the chip. This means the signals pass a switch which width is not wider than the width of two to three DNA chains. Therefore, such characteristic may be used for development of a solution to devices served as nodes greater than 5 nm.

In 2017 Symposia on VLSI Technology & Circuits, held in Kyoto, a novel transistor chip served as 5 nm node was made public. The best process was applied to stacking silicon nano-sheets of the transistor. The gate surrounding the transistor may carry out about 300 billion switches in a chip which size is about a nail. Therefore, such chip shows significant improvement on power and performance.

However, how to further increase density of device, power and performance in the practical manufacture process is the problem to be solved for technical researchers.

### SUMMARY OF THE INVENTION

In light of current technology, one aspect of the present invention is to provide a device of gate-all-around (GAA) quantum well complementary inverter and method of making the same with performance improvement.

To carry out one of above-mentioned or other object, an embodiment of the invention is to provide a semiconductor device, comprising a substrate, semiconductor nano-sheets on the substrate, a first semiconductor layer fully surrounding the semiconductor nano-sheets, a second semiconductor layer fully surrounding the first semiconductor layer, a gate area fully surrounding the second semiconductor layer, and a source area and a drain area oppositely positioned at two ends of the semiconductor nano-sheets, wherein the band gap width of the first semiconductor layer is smaller than that of the semiconductor nano-sheets to provide a quantum well for holes.

In accordance with some embodiments, the semiconductor nano-sheets may be silicon nano-sheets.

In accordance with some embodiments, the first semiconductor layer may comprise germanium.

In accordance with some embodiments, the first semiconductor layer may be compressive-strained Ge layer.

In accordance with some embodiments, the second semiconductor layer may provide a quantum well for electrons.

In accordance with some embodiments, the second semiconductor layer may be tensile-strained Si layer.

In accordance with some embodiments, the band gap width of the second semiconductor layer may be greater than that of the first semiconductor layer but smaller than that of the semiconductor nano-sheets.

In accordance with some embodiments, the semiconductor nano-sheets may have a width and a length, both of which are along with a horizontal direction, and a height perpendicular to the horizontal direction, the length may define a distance between the source area and the drain area, a cross-section profile along with the width may be like a track which comprises two semicircles at two ends and a rectangle connecting to the semicircles in the center.

In accordance with some embodiments, the gate area may comprise a gate dielectric layer fully surrounding the second semiconductor layer and a gate layer fully surrounding the gate dielectric layer.

To carry out one of above-mentioned or other object, an embodiment of the invention is to provide a method of making a semiconductor device, comprising steps of: providing a substrate, forming semiconductor nano-sheets on the substrate, forming a first semiconductor layer fully surrounding the semiconductor nano-sheets, forming a second semiconductor layer fully surrounding the first semiconductor layer, forming a gate area fully surrounding the second semiconductor layer, and forming a source area and a drain area at two ends of the semiconductor nano-sheets respectively, wherein the band gap width of the first semiconductor layer is smaller than that of the semiconductor nano-sheets.

In accordance with some embodiments, the method may further comprise forming silicon nano-sheets as the semiconductor nano-sheets.

In accordance with some embodiments, the method may further comprise forming the first semiconductor layer with SiGe material which mass concentration of Ge is no smaller than 50%.

In accordance with some embodiments, the method may further comprise forming compressive-strained Ge layer as the first semiconductor layer and forming tensile-strained Si layer as the second semiconductor layer.

In accordance with some embodiments, the method may further comprise forming the first semiconductor layer with epitaxial deposition process.

In accordance with some embodiments, the step of forming semiconductor nano-sheets on the substrate may further comprise forming rounded corners of the semiconductor nano-sheets with oxidation process and then wet etching process.

To carry out one of above-mentioned or other object, an embodiment of the invention is to provide a gate-all-around (GAA) quantum well complementary inverter, comprising: a substrate, a first field effect transistor (FET) and a second FET on the substrate, both the first FET and the second FET comprising a channel, a source area and a drain area oppositely positioned at two ends of the channel, and a gate area fully surrounding the channel, the channels of the first FET and the second FET being positioned side by side laterally, the channels comprising semiconductor nano-sheets on the substrate, a first semiconductor layer fully surrounding the semiconductor nano-sheets and a second semiconductor layer fully surrounding the first semiconductor layer, the first semiconductor layer providing a quantum well for holes, the second semiconductor layer providing a quantum well for electrons, and the gate area comprising a gate dielectric layer fully surrounding the channel and a gate layer fully surrounding the gate dielectric layer, and a common gate electrode connecting the gate layer of the first FET with the gate layer of the second FET and fully surrounding the gate layer of the first FET and the gate layer of the second FET.

In accordance with some embodiments, the first FET may be high electron mobility transistor (HEMT; high electron mobility transistor) and the second FET may be high hole mobility transistor (HHMT; high hole mobility transistor), the source area of the first FET may connect to an electric source V_{DD}, the drain area of the first FET may connect to the drain area of the second FET to serve as an output end Vₒᵤₜ, the source area of the second FET may connect to ground and the common gate electrode may serve as an input end Vᵢₙ.

In accordance with some embodiments, the semiconductor nano-sheets may have a width and a length, both of which are along with a horizontal direction, and a height perpendicular to the horizontal direction, the length may define a distance between the source area and the drain area, a cross-section profile along with the width may be like a track which comprises two semicircles at two ends and a rectangle connecting to the semicircles in the center.

In accordance with some embodiments, the semiconductor nano-sheets may be silicon nano-sheets.

In accordance with some embodiments, the first semiconductor layer may be compressive-strained Ge layer and the second semiconductor layer may be tensile-strained Si layer.

In accordance with some embodiments, each of the first FET and the second FET may comprise another channel arranged vertically with respect to the channel.

In accordance with some embodiments, an insulating layer underneath the first FET and the second FET to insulate the substrate may be further comprised.

To carry out one of above-mentioned or other object, an embodiment of the invention is to provide a method for making a GAA quantum well complementary inverter, comprising steps of: providing a substrate, forming a stack of sacrificial layer and semiconductor nano-sheets, both of which are layered alternately, defining at least two channel areas positioned side by side, etching the stack to form two sets of semiconductor nano-sheets, positioned side by side, corresponding to the channel areas respectively, and removing the sacrificial layer underneath the semiconductor nano-sheets to expose rim of the semiconductor nano-sheets and suspend the semiconductor nano-sheets above the substrate, forming a first semiconductor layer fully surrounding the two sets of semiconductor nano-sheets, a second semiconductor layer fully surrounding the first semiconductor layer, a gate dielectric layer fully surrounding the second semiconductor layer, and a gate layer fully surrounding the gate dielectric layer on the semiconductor nano-sheets, the first semiconductor layer providing a quantum well for holes and the second semiconductor layer providing a quantum well for electrons, forming a common gate electrode fully surrounding the gate layers of the two sets of semiconductor nano-sheets, and forming a source area and a drain area at two ends of the semiconductor nano-sheets.

In accordance with some embodiments the step of forming a stack of sacrificial layer and semiconductor nano-sheets may be performed with an epitaxial deposition process, the sacrificial layer may be epitaxial-grown SiGe layer and the semiconductor nano-sheets may be epitaxial-grown Si layer on the sacrificial layer.

In accordance with some embodiments, steps of oxidation and then wet-etching may be performed to form rounded corners of the semiconductor nano-sheets before the step of forming a first semiconductor layer on the semiconductor nano-sheets.

In accordance with some embodiments, the step of forming a first semiconductor layer may further comprise forming compressive-strained Ge layer on the semiconductor nano-sheets as the first semiconductor layer and the step of forming a second semiconductor layer may further comprise forming tensile-strained Si layer on the first semiconductor layer as the second semiconductor layer.

In accordance with some embodiments, a step of forming a shallow trench isolation structure on the substrate and a step of forming an insulation layer on the substrate may be performed.

In accordance with some embodiments, the semiconductor device, GAA quantum well complementary inverter and method for making a GAA quantum well complementary inverter disclosed here may bring benefits as follows: GAA is formed with the 3D structure of the stacked semiconductor nano-sheets and the channel fully surrounded by the gate. The device is compact because the common gate electrode may surround several channels at the same time. The device has better performance and capability to be shrunk further because the channel may be applied with silicon nano-sheets wrapped by the quantum well layer and a complementary converter is formed by HEMT and HHMT. Besides, the cross-section profile of the channel may be like a track to increase cross-sectional area of the channel, as well as driving current, and meanwhile sustain electrical integrity of the device.

Compared with current technology, the device disclosed here is compact and beneficial to increase density and performance with simple structure and therefore the device is easier to make.

### BRIEF DESCRIPTION OF THE DRAWINGS

Various objects and advantages of the present invention will be more readily understood from the following detailed description when read in conjunction with the appended drawing, in which:

FIGS. 1a-1b show diagrams of a gate-all-around (GAA) quantum well complementary inverter according to an embodiment of the invention, in which FIG. 1a is a top view and FIG. 1b is a cross-section view along AA′ direction indicated in FIG. 1a;

FIG. 2 shows a diagram of bandgap of materials according to an embodiment of the invention;

FIG. 3 shows a circuit diagram of the GAA quantum well complementary inverter according to an embodiment of the invention;

FIGS. 4a-4k show a flow chart of a method of making a GAA quantum well complementary inverter according to an embodiment of the invention.

### DESCRIPTION OF EMBODIMENTS OF THE INVENTION

For a more complete understanding of the present disclosure and its advantages, reference is now made to the following description taken in conjunction with the accompanying drawings, in which like reference numbers indicate like features. Persons having ordinary skill in the art will understand other varieties for implementing example embodiments, including those described herein. The drawings are not limited to specific scale and similar reference numbers are used for representing similar elements. As used in the disclosures and the appended claims, the terms “example embodiment,” “exemplary embodiment,” and “present embodiment” do not necessarily refer to a single embodiment, although it may, and various example embodiments may be readily combined and interchanged, without departing from the scope or spirit of the present disclosure.

It is to be understood that these embodiments and drawings are not meant as limitations of the invention but merely exemplary descriptions of the invention with regard to certain specific embodiments. Indeed, different numbers, shapes and sizes of elements may be apparent to those skilled in the art without departing from the scope of the annexed claims.

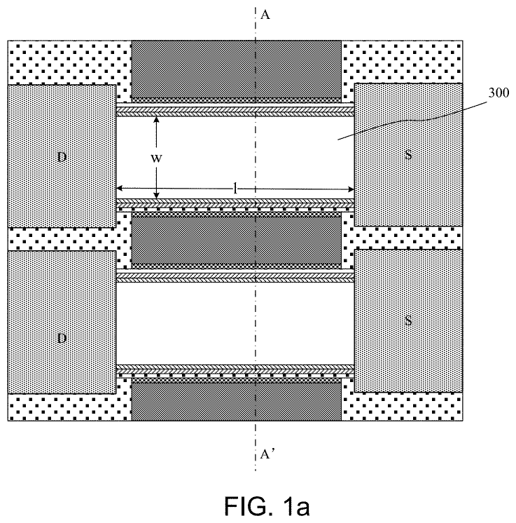

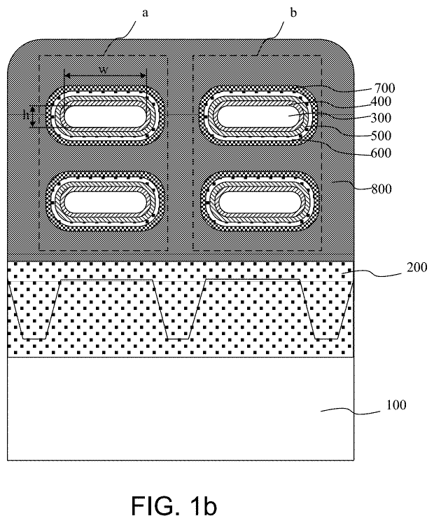

Please refer to FIGS. 1a and 1b, which show diagrams of a gate-all-around (GAA) quantum well complementary inverter according to an embodiment of the invention. The GAA quantum well complementary inverter comprises a substrate 100, a first field effect transistor (FET) a, a second FET b, and a common gate electrode 800, on the substrate 100. FIG. 1a is a top view and FIG. 1b is a cross-section view along AA′ direction indicated in FIG. 1a.

The substrate 100 may be a typical bulk silicon substrate or other proper semiconductor substrate. On the substrate 100, an insulation layer 200 is positioned to insulate the first FET a and the second FET b.

The first FET a and the second FET b both are GAA non-planar transistor. The structure are basically the same, comprising a channel, a source area S and a drain area D oppositely positioned at two ends of the channel, and a gate area fully surrounding the channel. The first FET a and the second FET b are positioned side by side laterally.

The channel comprises semiconductor nano-sheets 300 on the substrate 100, a first semiconductor layer 400 fully surrounding the semiconductor nano-sheets 300 and a second semiconductor layer 500 fully surrounding the first semiconductor layer 400, and the gate area comprising a gate dielectric layer 600 fully surrounding the channel and a gate layer 700 fully surrounding the gate dielectric layer 600, and a dielectric layer served as a spacer positioned between the source area S and the drain area D, and the gate area and a common gate electrode 800. The first semiconductor layer 400 may provide a quantum well for holes, the second semiconductor layer 500 may provide a quantum well for electrons.

The common gate electrode 800 may fully surround the gate layer 700 of the first FET a and the gate layer 700 of the second FET b to connect the gate layer 700 of the first FET a with the gate layer 700 of the second FET b.

Specifically, the semiconductor nano-sheets 300 may be silicon nano-sheets which may have a width w and a length l, both of which are along with a horizontal direction, and a height h perpendicular to the horizontal direction. The height h may be 10-100 nm. The length l may define a distance between the source area S and the drain area D. Along the width w of the semiconductor nano-sheets 300, a cross-section profile may be like a track, as shown in FIG. 1b, which comprises two semicircles at two ends and a rectangle connecting to the semicircles in the center. Such profile may increase the cross-sectional area of the channel to increase driving current and meanwhile sustain electrical integrity of the device.

The first semiconductor layer 400 may serve as a quantum well layer for holes, which bandgap should be higher than that of the semiconductor nano-sheets 300. Specifically, the first semiconductor layer 400 may be formed by material containing Ge, such as SiGe material containing no lower than 50% (mass concentration) Ge.

Preferably, the bandgap width of the first semiconductor layer 400 may be smaller than that of the semiconductor nano-sheets 300, the bandgap width of the second semiconductor layer 500 may be greater than that of the first semiconductor layer 400 but slightly smaller than that of the semiconductor nano-sheets 300. Specifically, the first semiconductor layer 400 may be compressive-strained Ge (s-Ge) layer and the second semiconductor layer 500 may be tensile-strained Si (s-Si) layer.

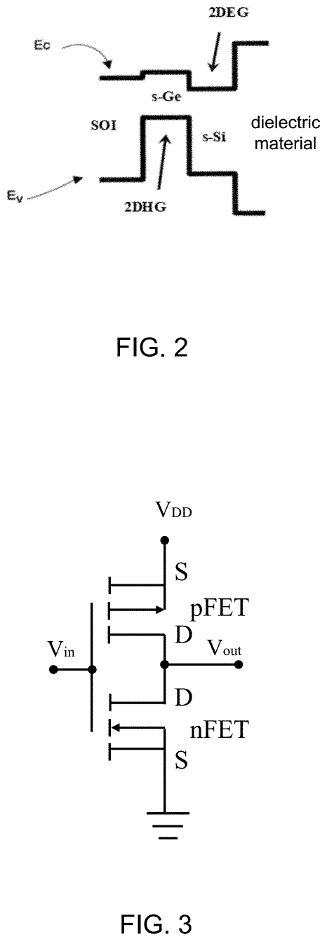

FIG. 2 shows a diagram of bandgap of SOI (silicon-on-insulator), s-Ge, s-Si and dielectric materials. As shown, the bandgap width of s-Ge is smaller than that of SOI, the bandgap width of s-Si is greater than that of s-Ge but slightly smaller than that of SOI. The bandgap of s-Ge is higher than that of SOI, which means a quantum well for holes is formed on the top end Eᵥ of the valance band, so that 2DHG (Two-dimensional hole gas) may be generate here. The bandgap width of s-Si is smaller than that of dielectric, which means a quantum well for electrons is formed on the bottom end E_{c} of the conduction band, so that 2DEG (Two-dimensional electron gas) may be generate here. In the present embodiment, when the semiconductor nano-sheets 300 are silicon nano-sheets, the first semiconductor layer 400 is compressive-strained Ge (s-Ge) layer and the second semiconductor layer 500 is tensile-strained Si (s-Si) layer, the first semiconductor layer 400 may serve as quantum well layer for holes and the second semiconductor layer 500 may serve as quantum well layer for electrons.

The GAA quantum well complementary inverter may apply the circuit of complementary inverter as shown in FIG. 3. The first FET a may be HEMT (high electron mobility transistor), i.e. pEFT, and the second FET b may be HHMT (high hole mobility transistor), i.e. nEFT. The source area S of the first FET a may connect to an electric source V_{DD}, the drain area D of the first FET a may connect to the drain area D of the second FET b to serve as an output end Vₒᵤₜ, the source area S of the second FET b may connect to ground and the common gate electrode 800 may serve as an input end Vᵢₙ.

Besides, preferably, the first FET a and the second FET b may comprise another channel arranged vertically with respect to the channel to promote the performance. In the present embodiment, each transistor may correspond to upper and lower channels. However, in other embodiments, each transistor may correspond to more channels.

Here a method for making a GAA quantum well complementary inverter is introduced along with the drawings.

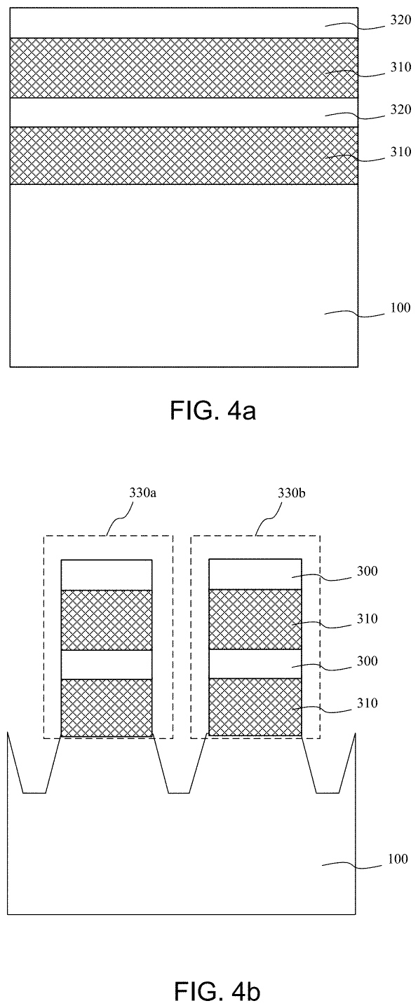

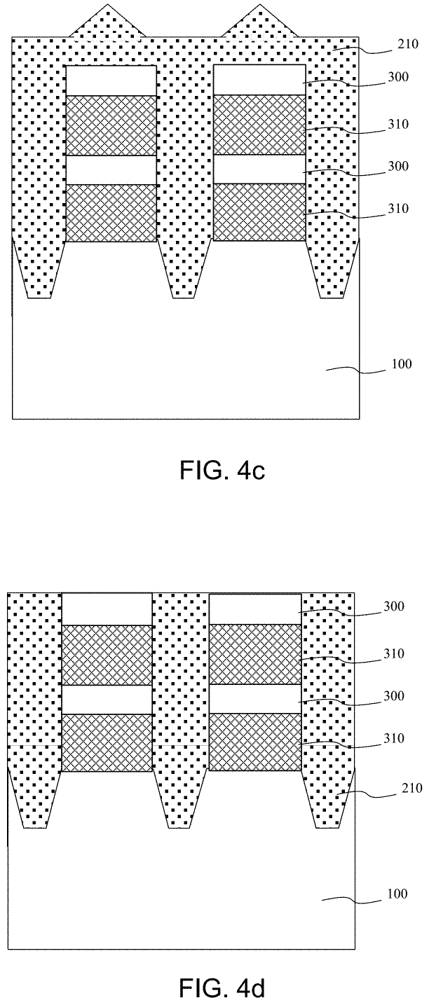

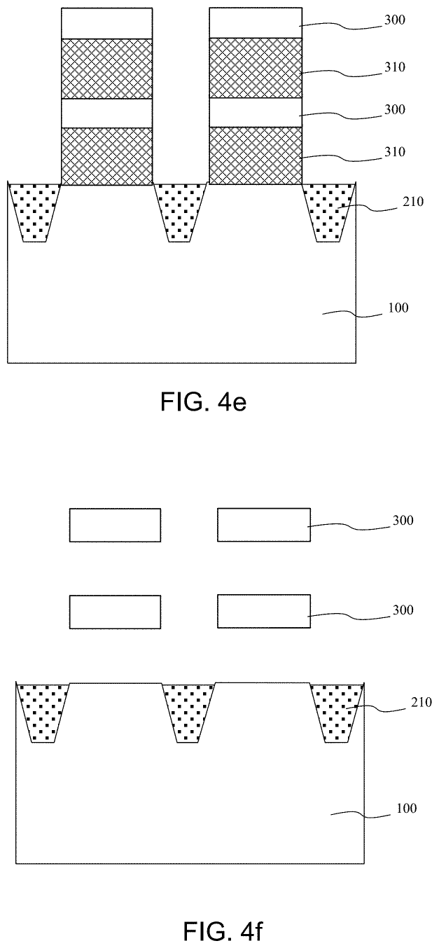

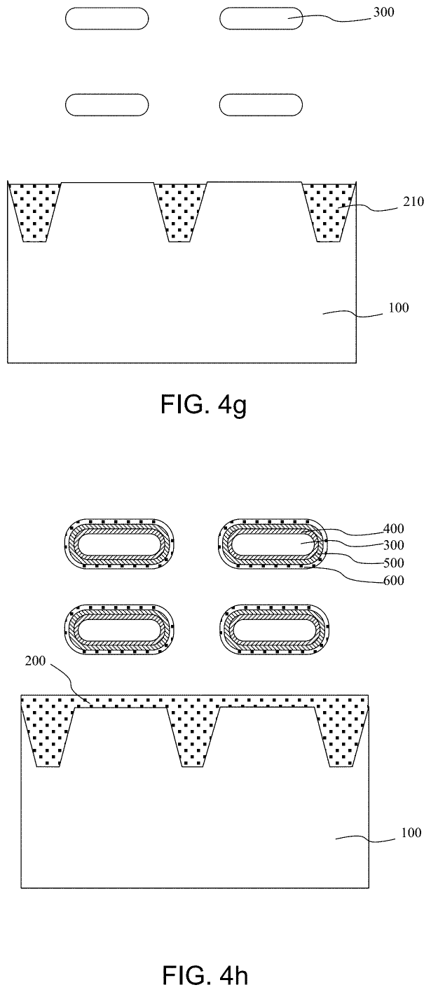

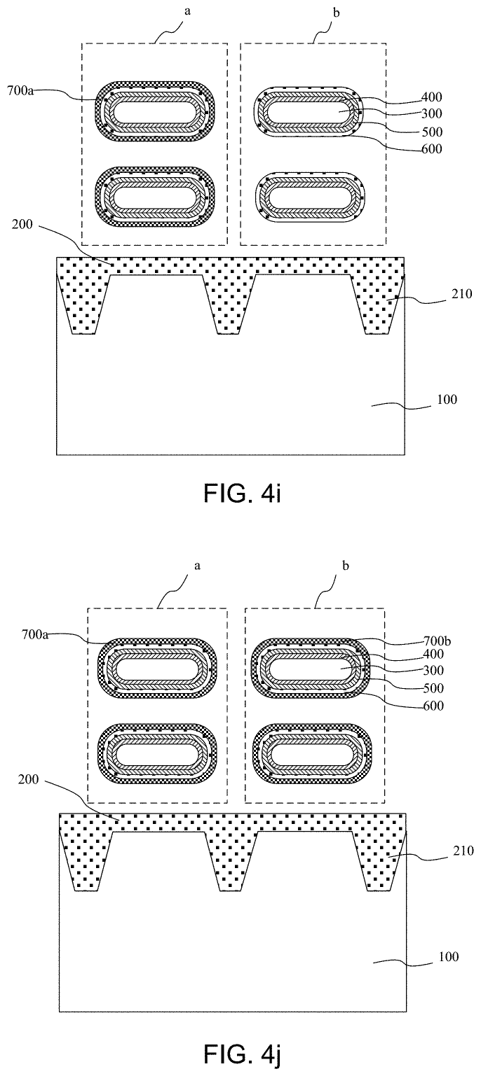

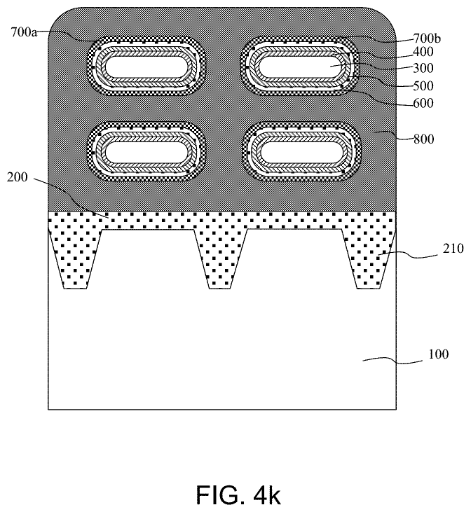

As shown in FIGS. 4a-4k, the method for making a GAA quantum well complementary inverter provided by the present embodiment comprises steps S1-S6.

Step S1 is providing a substrate 100. The substrate 100 may be typical bulk silicon substrate or other proper semiconductor substrate.

Step S2 is forming a stack of sacrificial layer 310 and semiconductor nano-sheets 320, both of which are layered alternately, as shown in FIG. 4a.

Specifically, the stack may be formed with an epitaxial deposition process on the substrate 100. For example, the sacrificial layer 310 may be epitaxial-grown SiGe layer on the substrate 100, and then the semiconductor nano-sheets 320 may be epitaxial-grown Si layer on the sacrificial layer 310. The thickness of the sacrificial layer 310 may be 10-200 nm, and that of the semiconductor nano-sheets 320 may be 10-100 nm. In the present embodiment, two layers of sacrificial layer 310 and semiconductor nano-sheets 320 are stacked in the stack. However, in other embodiments, more layers may be applied to provide more number of channels.

Step S3 is defining at least two channel areas positioned side by side, etching the stack to form two sets of semiconductor nano-sheets 300, positioned side by side, and removing the sacrificial layer 310 underneath the semiconductor nano-sheets 300 to expose rim of the semiconductor nano-sheets 300 and suspend the semiconductor nano-sheets 300 above the substrate 100.

As shown in FIG. 4b, a step of forming a shallow trench isolation (STI) structure on the substrate and meanwhile defining at least two channel areas, positioned side by side, with lithography and etching processes may be performed first. For example, the two channel areas may correspond to the first channel area 330a of the first FET a and the second channel area 330b of the second FET b. The trench extends from the surface of the stack to the inner of the substrate 100. When etching the trench, two sets of semiconductor nano-sheets 300, i.e. the silicon nano-sheets, positioned side by side, corresponding to the first channel area 330a and the second channel area 330b respectively, are formed.

Then, as shown in FIG. 4c, insulation material 210 fills up the trench, and then as shown in FIG. 4d, CMP (chemical mechanical polish) is applied to planar the surface of the structure and avoid from residual of the material on the semiconductor nano-sheets 300. Then, as shown in FIG. 4e, with lithography and etching processes, insulating material around the first channel area 330a and the second channel area 330b is removed, and the insulating material 210 filling up the substrate 100 is kept.

Then, anisotropic horizontal etching may be performed to remove the sacrificial layer 310 underneath the semiconductor nano-sheets 300. As shown in FIG. 4f, the surrounding of the semiconductor nano-sheets 300 may be exposed and suspended over the substrate 100. In the present embodiment, etchant comprising HF, HNO₃, H₂O may be applied to remove the SiGe sacrificial layer 310.

To form the cross-section profile of a track, after the sacrificial layer 310 is removed, the semiconductor nano-sheets 300 may be oxidized and then wet-etched to form rounded corners. As shown in FIG. 4g, the semiconductor nano-sheets 300 may be oxidized first, and then the oxidized layer may be removed by DHF etchant to shape the semiconductor nano-sheets 300 to be like a track roughly. Then, they may be undergone helium annealing between 800° C.-1200° C. for 5 mins to 8 hrs. Afterwards, the surface of the semiconductor nano-sheets 300 may be smoother and denser.

Step S4: Forming a first semiconductor layer 400 fully surrounding the semiconductor nano-sheets 300, a second semiconductor layer 500 fully surrounding the first semiconductor layer 400, a gate dielectric layer 600 fully surrounding the second semiconductor layer 500 and a gate layer 700 fully surrounding the gate dielectric layer 600. The first semiconductor layer 400 may provide a quantum well for holes and the second semiconductor layer 500 may provide a quantum well for electrons.

As shown in FIG. 4h, a compressive-strained Ge layer may be grown epitaxially on the semiconductor nano-sheets 300 as the first semiconductor layer 400, and a tensile-strained Si layer may be grown epitaxially on the first semiconductor layer 400 as the second semiconductor layer 500, and then high-k dielectric material may be deposited with a CVD (Chemical Vapor Deposition) or ALD (Atomic Layer Deposition) process as the gate dielectric layer 600. During the formation of the gate dielectric layer 600, the insulation layer 200 may be formed on the exposed surface of the substrate 100.

When forming the gate layer 700, as shown in FIGS. 4i and 4j, a gate material may be deposited with a CVD or ALD process to form a first gate layer 700a corresponding to the first FET a on the gate dielectric layer 600, and the gate material corresponding to the second FET b may be removed, and then another gate material may be deposited with a CVD or ALD process to form a second gate layer 700b corresponding to the second FET b, and residual gate material on the first gate layer 700a is then removed. This means the first gate layer 700a may be formed first and then the second gate layer 700b may be formed. The gate material of the first gate layer 700a may comprise TiN, TaN, TiAl, Ti or other suitable gate materials. The gate material of the second gate layer 700b may comprise TiN, TaN, TiAl, Ti or other suitable gate materials.

Step S5: Forming a common gate electrode 800 which fully surrounding the gate layer 700 on the two sets of semiconductor nano-sheets 300 at the same time. As shown in FIG. 4k, the common gate electrode 800 may fully surround the first gate layer 700a and the second gate layer 700b and joint them together. The material to form the common gate electrode 800 may comprise conductor such as Al, W, Cu.

Step S6: Forming a source area and a drain area (not shown) at two ends of the semiconductor nano-sheets 300 respectively to finish the manufacturing of the first FET a and the second FET b. The first FET a may be HEMT and the second FET b may be HHMT.

Finally, as shown in FIG. 3, forming the complementary invertor a complete invertor, comprising forming wires of source and drain. Because the channels of HEMT and HHMT are positioned side by side laterally, it may be easier to connect and forming wires of the source and drain of them and form a denser component to integration.

To sum up, the present invention may provide a 3-D structure with stacked silicon nano-sheets to form a gate fully surrounding the surface of a channel, a GAA, and a common gate surrounding several channels at the same time to form a denser structure. Then, with the channels which apply a quantum well layer wrapping the silicon nano-sheets, the device as a complementary invertor formed by HEMT and HHMT may carry out a better performance and capability to shrink in size. Further, the track-like cross-section profile of the channels may increase the cross-sectional area of the channel to increase the driving current and sustain electrical integrity at the same time.

Compared with current device, those provided by the present invention may be denser with higher device density, better performance, more simple structure, and lower barrier to make. Therefore, the present invention overcomes various drawbacks in the current technology.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor device, comprising:
a substrate;
semiconductor nano-sheets on the substrate;
a first semiconductor layer, fully surrounding the semiconductor nano-sheets;
a second semiconductor layer, fully surrounding the first semiconductor layer;
a gate area, fully surrounding the second semiconductor layer; and
a source area and a drain area, oppositely positioned at two ends of the semiconductor nano-sheets;
wherein the band gap width of the first semiconductor layer is smaller than that of the semiconductor nano-sheets to provide a quantum well for holes.

2. The semiconductor device according to claim 1, wherein the semiconductor nano-sheets are silicon nano-sheets.

3. The semiconductor device according to claim 1, wherein the first semiconductor layer comprises germanium.

4. The semiconductor device according to claim 1, wherein the first semiconductor layer is compressive-strained Ge layer.

5. The semiconductor device according to claim 1, wherein the second semiconductor layer provides a quantum well for electrons.

6. The semiconductor device according to claim 1, wherein the second semiconductor layer is tensile-strained Si layer.

7. The semiconductor device according to claim 1, wherein the band gap width of the second semiconductor layer is greater than that of the first semiconductor layer but smaller than that of the semiconductor nano-sheets.

8. The semiconductor device according to claim 1, wherein the semiconductor nano-sheets have a width and a length, both of which are along with a horizontal direction, and a height perpendicular to the horizontal direction, the length defines a distance between the source area and the drain area, a cross-section profile along with the width is like a track which comprises two semicircles at two ends and a rectangle connecting to the semicircles in the center.

9. The semiconductor device according to claim 1, wherein the gate area comprises a gate dielectric layer fully surrounding the second semiconductor layer and a gate layer fully surrounding the gate dielectric layer.

10. A method of making a semiconductor device, comprising steps of:
providing a substrate;
forming semiconductor nano-sheets on the substrate;
forming a first semiconductor layer fully surrounding the semiconductor nano-sheets;
forming a second semiconductor layer fully surrounding the first semiconductor layer;
forming a gate area fully surrounding the second semiconductor layer; and
forming a source area and a drain area at two ends of the semiconductor nano-sheets respectively;
wherein the band gap width of the first semiconductor layer is smaller than that of the semiconductor nano-sheets.

11. The method according to claim 10, further comprising forming silicon nano-sheets as the semiconductor nano-sheets.

12. The method according to claim 10, further comprising forming the first semiconductor layer with SiGe material which mass concentration of Ge is no smaller than 50%.

13. The method according to claim 10, further comprising forming compressive-strained Ge layer as the first semiconductor layer and forming tensile-strained Si layer as the second semiconductor layer.

14. The method according to claim 10, further comprising forming the first semiconductor layer with epitaxial deposition process.

15. The method according to claim 10, wherein the step of forming semiconductor nano-sheets on the substrate further comprises forming rounded corners of the semiconductor nano-sheets with oxidation process and then wet etching process.

16. A gate-all-around (GAA) quantum well complementary inverter, comprising:
a substrate;
a first field effect transistor (FET) and a second FET on the substrate, both the first FET and the second FET comprising a channel, a source area and a drain area oppositely positioned at two ends of the channel, and a gate area fully surrounding the channel, the channels of the first FET and the second FET being positioned side by side laterally, the channels comprising semiconductor nano-sheets on the substrate, a first semiconductor layer fully surrounding the semiconductor nano-sheets and a second semiconductor layer fully surrounding the first semiconductor layer, the first semiconductor layer providing a quantum well for holes, the second semiconductor layer providing a quantum well for electrons, and the gate area comprising a gate dielectric layer fully surrounding the channel and a gate layer fully surrounding the gate dielectric layer; and
a common gate electrode, connecting the gate layer of the first FET with the gate layer of the second FET and fully surrounding the gate layer of the first FET and the gate layer of the second FET.

17. The GAA quantum well complementary inverter according to claim 16, wherein the first FET is high electron mobility transistor and the second FET is high hole mobility transistor, the source area of the first FET connects to an electric source, the drain area of the first FET connects to the drain area of the second FET to serve as an output end, the source area of the second FET connects to ground and the common gate electrode serves as an input end.

18. The GAA quantum well complementary inverter according to claim 16, wherein the semiconductor nano-sheets have a width and a length, both of which are along with a horizontal direction, and a height perpendicular to the horizontal direction, the length defines a distance between the source area and the drain area, a cross-section profile along with the width is like a track which comprises two semicircles at two ends and a rectangle connecting to the semicircles in the center.

19. The GAA quantum well complementary inverter according to claim 16, wherein the semiconductor nano-sheets are silicon nano-sheets.

20. The GAA quantum well complementary inverter according to claim 16, wherein the first semiconductor layer is compressive-strained Ge layer and the second semiconductor layer is tensile-strained Si layer.

21. The GAA quantum well complementary inverter according to claim 16, wherein each of the first FET and the second FET comprises another channel arranged vertically with respect to the channel.

22. The GAA quantum well complementary inverter according to claim 16, further comprising an insulating layer underneath the first FET and the second FET to insulate the substrate.

23. A method for making a gate-all-around (GAA) quantum well complementary inverter, comprising steps of:
providing a substrate;
forming a stack of sacrificial layer and semiconductor nano-sheets, both of which are layered alternately;
defining at least two channel areas positioned side by side, etching the stack to form two sets of semiconductor nano-sheets, positioned side by side, corresponding to the channel areas respectively, and removing the sacrificial layer underneath the semiconductor nano-sheets to expose rim of the semiconductor nano-sheets and suspend the semiconductor nano-sheets above the substrate;
forming a first semiconductor layer fully surrounding the two sets of semiconductor nano-sheets, a second semiconductor layer fully surrounding the first semiconductor layer, a gate dielectric layer fully surrounding the second semiconductor layer, and a gate layer fully surrounding the gate dielectric layer on the semiconductor nano-sheets, the first semiconductor layer providing a quantum well for holes and the second semiconductor layer providing a quantum well for electrons;
forming a common gate electrode, fully surrounding the gate layers of the two sets of semiconductor nano-sheets; and
forming a source area and a drain area at two ends of the semiconductor nano-sheets.

24. The method according to claim 23, wherein the step of forming a stack of sacrificial layer and semiconductor nano-sheets is performed with an epitaxial deposition process, the sacrificial layer is epitaxial-grown SiGe layer and the semiconductor nano-sheets is epitaxial-grown Si layer on the sacrificial layer.

25. The method according to claim 23, further comprising a step of oxidation and then a step of wet-etching to form rounded corners of the semiconductor nano-sheets before the step of forming a first semiconductor layer on the semiconductor nano-sheets.

26. The method according to claim 23, wherein the step of forming a first semiconductor layer further comprises forming compressive-strained Ge layer on the semiconductor nano-sheets as the first semiconductor layer and the step of forming a second semiconductor layer further comprises forming tensile-strained Si layer on the first semiconductor layer as the second semiconductor layer.

27. The method according to claim 23, further comprising a step of forming a shallow trench isolation structure on the substrate and a step of forming an insulation layer on the substrate.
